(19) United States
(12) Patent Application Publication
(10) Pub. No.: US 2006/0049040 A1
(43) Pub. Date: Mar. 9, 2006

(54) Apparatus and method for two dimensional magnetron scanning for sputtering onto flat panels

(75) Inventor: Avi Tepman, Cupertino, CA (US)

Correspondence Address: Applied Materials, Inc.;Patent / Legal Dept., M/S 2061, P.O. Box 450A, Santa Clara, CA, 95052, US

(73) Assignee: APPLIED MATERIALS, INC.

(21) Appl. No.: 11/211,141

(22) Filed: Aug. 24, 2005

Related U.S. Application Data
(63) Continuation-in-part of application No. 10/863,152, filed on Jun. 7, 2004.
(60) Provisional application No. 60/534,952, filed on Jan. 7, 2004.
(60) Provisional application No. 60/702,327, filed on Jul. 25, 2005.
(60) Provisional application No. 60/705,031, filed on Aug. 2, 2005.

(51) Int. Cl. C23C 14/00

(52) U.S. Cl. 204/298.02; 204/192.12

(57) ABSTRACT

A rectangular magnetron placed at the back of a rectangular target to intensify the plasma in a sputter reactor configured for sputtering target material onto a rectangular panel. The magnetron has a size only somewhat less than that of the target and is scanned in the two perpendicular directions of the target with a scan length of, for example, about 100 mm for a 2 m target. The scan may follow a double-Z pattern along two links parallel to a target side and the two connecting diagonals. The magnetron includes a closed plasma loop formed in a convolute shape, for example, a rectangularized helix with an inner pole of nearly constant width extending along a single path and having one magnetic polarity completely surrounded by an outer pole having the opposed polarity. External actuators move the magnetron slidably suspended from a gantry which sliding perpendicularly on the chamber walls.

### RELATED APPLICATIONS

This application is a continuation in part of Ser. No. 10/863,152, filed Jun. 7, 2004, which claims benefit of provisional application 60/534,952, filed Jan. 7, 2004. This application also claims benefit of provisional application 60/702,327 filed Jul. 25, 2005 and 60/705,031 filed Aug. 2, 2005, both incorporated herein by reference.

### FIELD OF THE INVENTION

The invention relates generally to sputtering of materials. In particular, the invention relates to scanning of the magnetron creating a magnetic field to enhance sputtering from rectangular targets.

### BACKGROUND ART

Over the past decade, the technology has been intensively developed for fabricating flat panel displays, such as used for computer displays and more recently for television screens. Sputtering is the preferred approach in fabricating flat panels for depositing conductive layers including metals such as aluminum and molybdenum and transparent conductors such as indium tin oxide (ITO) onto large generally rectangular panels of glass or polymeric sheets. The completed panel may incorporate thin-film transistors, plasma displays, field emitters, liquid crystal display (LCD) elements, or organic light emitting diodes (OLEDs). Similar technology may be used for coating glass windows with optical layers. Flat panel sputtering is principally distinguished from the long developed technology of wafer sputtering by the large size of the substrates and their rectangular shape. Demaray et al. describe such a flat panel sputter reactor in U.S. Pat. No. 5,565,071, incorporated herein by reference in its entirety. Their reactor includes, as illustrated in the schematic cross section of FIG. 1, a rectangularly shaped sputtering pedestal electrode 12, which is typically electrically grounded, for holding a rectangular glass panel 14 or other substrate in opposition to a rectangular sputtering target 16 within a vacuum chamber 18. The target 16, at least the surface of which is composed of a metal to be sputtered, is vacuum sealed to the vacuum chamber 18 across an isolator 20. Typically, a layer of the material to be sputtered is bonded to a backing plate in which cooling water channels are formed to cool the target 16. A sputtering gas, typically argon, is supplied into the vacuum chamber 18 held at a pressure in the milliTorr range. Advantageously, a back chamber 22 is vacuum sealed to the back of the target 16 and vacuum pumped to a low pressure, thereby substantially eliminating the pressure differential across the target 16 and its backing plate. Thereby, the target assembly can be made much thinner. When a negative DC bias is applied to the conductive target 16 with respect to the pedestal electrode 12 or other grounded parts of the chamber such as wall shields, the argon is ionized into a plasma. The positive argon ions are attracted to the target 16 and sputter metal atoms from it. The metal atoms are partially directed to the panel 14 and deposit thereon a layer at least partially composed of the target metal. Metal oxide or nitride may be deposited in a process called reactive sputtering by additionally supplying oxygen or nitrogen into the chamber 18 during sputtering of the metal.

To increase the sputtering rate, a linear magnetron 24, also illustrated in schematic bottom view in FIG. 2, is conventionally placed in back of the target 16. It has a central pole 26 of one vertical magnetic polarity surrounded by an outer pole 28 of the opposite polarity to project a magnetic field within the chamber 18 and parallel to the front face of the target 16. The two poles 26, 28 are separated by a substantially constant gap 30 over which a high-density plasma is formed in the chamber 18 under the correct chamber conditions and flows in a close loop or track. The outer pole 28 consists of two straight portions 32 connected by two semi-circular arc portions 34. The magnetic field traps electrons and thereby increases the density of the plasma and as a result increases the sputtering rate of the target 16. The relatively small widths of the linear magnetron 24 and of the gap 30 produces a higher magnetic flux density. The closed shape of the magnetic field distribution along a single closed track forms a plasma loop generally following the gap 30 and prevents the plasma from leaking out the ends. However, the small size of the magnetron 24 relative to the target 16 requires that the magnetron 24 be linearly and reciprocally scanned across the back of the target 16. Typically, a lead screw mechanism drives the linear scan, as disclosed by Halsey et al. in U.S. Pat. No. 5,855,744 in the context of a more complicated magnetron. Although horseshoe magnets may be used, the preferred structure includes a large number of strong cylindrical magnets, for example, of NdBFe arranged in the indicated pole shapes with their orientations inverted between the two indicated polarities. Magnetic pole pieces may cover the operating faces to define the pole surfaces and a magnetic yoke bridging the two poles 26, 28 may magnetically couple the other sides of the magnets.

De Bosscher et al. have described a coupled two-dimensional scan of such a linear magnetron in U.S. Pat. Nos. 6,322,679 and 6,416,639.

The described magnetron was originally developed for rectangular panels having a size of about 400 mm×600 mm. However, over the years, the panel sizes have continued to increase, both for economy of scale and to provide larger display screens. Reactors are being developed to sputter onto panels having a size of about 2 m×2 m. One generation processes a panel having a size of 1.87 m×2.2 m and is called 40 K because its total area is greater than 40,000 cm². A follow-on generation called 50 K has a size of greater than 2 m on each side. The widths of linear magnetrons are generally constrained to be relatively narrow if they are to produce a high magnetic field. As a result, for larger panels having minimum dimensions of greater than 1.8 m, linear magnetrons become increasingly ineffective and require longer deposition periods to uniformly sputter the larger targets and coat the larger substrates.

In one method of accommodating larger targets, the racetrack magnetron 24 of FIG. 2 is replicated up to nine time in the transverse direction along the scanning direction to cover a substantial portion of the target. See U.S. Pat. No. 5,458,759 to Hosokawa et al. Scanning is still desired to average out the magnetic field distribution. However, there are several disadvantages to this replication approach. First, the separated magnetrons are not believed to optimally utilize the magnetic fields of the constituent magnets. That is, the effective magnetic field is less than is possible. Secondly, a significant number of particles have been observed to be produced during striking of the plasma at the portions of the magnetron near to the plasma dark space shields, which are adjacent to the arc portions 34 of the outer pole 28 of the racetrack magnetron 24. It is believed that electrons leak from the plasma to the nearby shield. Striking voltages of about 800VDC are required. Such high voltages are believed to disadvantageously produce excessive particles. Thirdly, the prior art using one racetrack magnetron 24 of FIG. 2 reciprocally scans the magnetron at a relatively high speed over a large fraction of the target size to perform approximately 30 to 40 scans during a typical one minute sputter deposition period. Such high scanning rates require a difficult mechanical design for the much heavier magnetrons covering a substantial fraction of the larger target. Fourthly, scanning magnetrons including one or more racetrack magnetrons do not completely solve the uniformity problem. The lateral edge portions of the target 16 underlying the ends of the racetrack magnetron 24 receive a high time-integrated magnetic flux because the arc portions 34 extend in large part along the scan direction. Also, the axial edge portions of the target underlying the magnetron when the scan direction reverses also receive a high time-integrated magnetic flux because of the finite time need to reverse directions. Thus, the target edges are disproportionately eroded, reducing the target utilization and target lifetime, as well as contributing to non-uniform deposition.

### SUMMARY OF THE INVENTION

One aspect of the invention includes a magnetron having a convolute plasma loop, particularly one having a generally rectangular outline. The loop may be arranged in a serpentine shape having parallel straight portions connected by curved portions or in a rectangularized helical shape having straight portions arranged along orthogonal directions. The plasma loop may be formed between an inner magnetic pole of one magnetic polarity formed in a convolute shape surrounded by an outer pole of the opposed magnetic polarity. Preferably, the inner magnetic pole has a simple folded shape describable as extending along a single path with two ends. The uniformity of the sputter erosion is increased if one or two external ends of the plasma loop are extended in tails extending outwardly of the useful rectangular outline.

The convolute shape follows a path preferably having straight portions constituting at least 50% and preferably more than 75% of the total path length.

The plasma loop follows a folded track bracketed by the two poles with parallel portions separated by a pitch of between 50 to 125 mm, 75 mm having been established to provide superior results. The scan should be over a distance greater than the pitch, for example, at least 10 mm greater.

The magnetron is only somewhat smaller than the target being scanned, and the target may be relatively large in correspondence to a rectangular flat panel substrate with a minimum dimension of at least 1.8 m. The magnetron may have effective fields extending within an area having sides that are at least 80% and even more than 90% of the corresponding dimensions of the target.

Another aspect of the invention includes scanning a magnetron along two dimensions of a rectangularly shaped target. It is possible to scan along a single diagonal of the rectangular target. It is, however, preferable, that the two dimensions of scanning not be fixed together. The scan speed can be relatively low, for example 0.5 to 5 mm/s with corresponding scan periods of between 20 to 200 s. A single scan period may be sufficient for a panel.

A preferred scan pattern is a double-Z including a continuous scan along two opposed sides of a rectangle aligned with the lateral sides of the target and along the two diagonals connecting the ends of the rectangle sides. The target power may be turned off or reduced on the scan along the sides or may be left on if the magnetron is sufficiently spaced from the frame at the edge of the target. The double-Z scan may be repeated with small displacements between the scans, preferably in a direction perpendicular to the two lateral sides, and more preferably with displacements between adjacent scans being in one and then the other perpendicular directions. The displacement offsets may be in a range of 5 to 15 mm, preferably 8 to 12 mm.

Diagonal and other scans oblique to the Cartesian coordinates of the target are preferably achieved in a zig-zag pattern along the Cartesian coordinates with each of the rectilinear portions of the zig-zag pattern preferably having a length of between 0.4 to 3 mm and more preferably 0.8 to 1.2 mm.

Yet another aspect of the invention moves the scanned magnetron away from the grounded frame or shield defining the chamber wall before igniting the plasma, preferably by a distance of between 1 and 5 mm.

### BRIEF DESCRIPTION OF THE DRAWINGS

FIG. 1 is a schematic side view of a convention plasma sputter reactor configured for sputter depositing onto a rectangular flat panel.

FIG. 2 is a plan view of a convention linear, racetrack magnetron usable with the sputter reactor of FIG. 1.

FIG. 3 is a schematic plan view of a serpentine magnetron according to one aspect of the invention.

FIG. 4 is a schematic plan view of a rectangularized spiral magnetron of the invention.

FIG. 5 is a more realistic plan view of a serpentine magnetron.

FIG. 6 is a plan view of an improved serpentine magnetron.

FIG. 7 is a plan view of an alternative embodiment of a serpentine magnetron.

FIG. 8 is a more realistic plan view of a rectangularized spiral magnetron.

FIG. 9 is a cross-sectional view of a retainer used to capture cylindrical magnets.

FIG. 10 is a plan view of retainers screwed to a magnetic back plate and capturing magnets forming a magnetron.

FIG. 10 is a plan view of two retainers capturing magnets.

FIG. 11 is an elevational view of a linear scan mechanism having the magnetron slidably supported on the target.

FIG. 12 is plan view of diagonal scan mechanism.

FIG. 13 is a graph showing the variation of target voltage with scan position.

FIG. 14 is plan view of a linear scan mechanism combined with an inclined magnetron achieving some of the results of a diagonal scan.

FIG. 15 is a plan view of a first embodiment of a two-dimensional scan mechanism.

FIG. 16 is a plan view of a second embodiment of a two-dimensional scan mechanism.

FIG. 17 is an orthographic view of a third embodiment of a two-dimensional scan mechanism and a support structure for the magnetron.

FIG. 18 is an exploded orthographic view of a fourth embodiment of a two-dimensional scan mechanism.

FIGS. 19 and 20 are detailed orthographic views of the actuators portions the scan mechanism of FIG. 18.

FIG. 21 is a map of a double-Z scan path.

FIG. 22 is a map of a path for a sequence of offset double-Z scans.

FIGS. 23 and 24 contain a map of a path of a sequence of double-Z scans offset in orthogonal directions.

FIG. 25 contains a map of a serpentine scan path.

FIG. 26 is a map of a zig-zag diagonal scan path.

FIG. 27 is a map of a figure-8 scan as an example of a two-dimensional curved scan path.

### DETAILED DESCRIPTION OF THE PREFERRED EMBODIMENTS

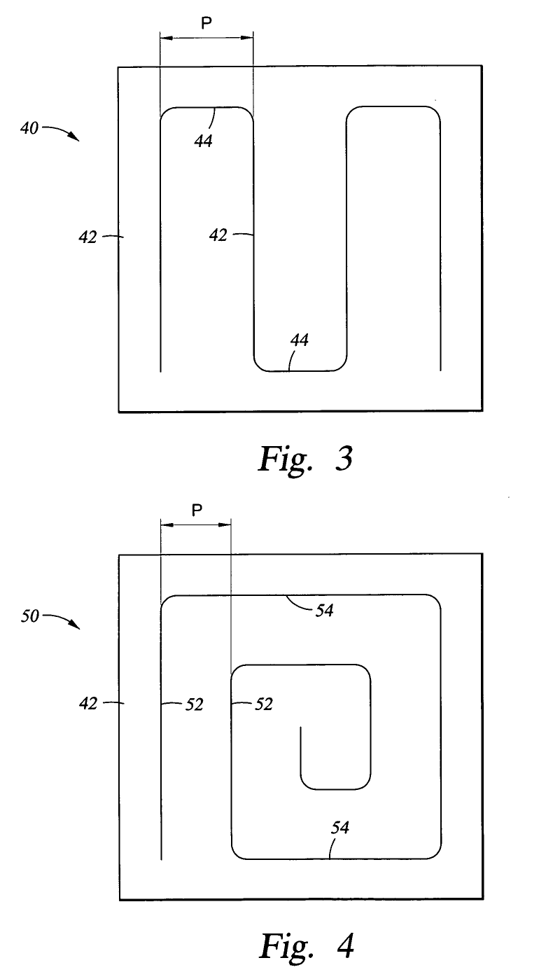

One aspect of the invention includes shapes for the magnetron that are more convoluted than the linear racetrack of FIG. 2. By convolute is meant a magnetron forming a closed plasma track including curved sections extending in sum over greater than 360° of arc and preferably greater than 7200. In one embodiment illustrated schematically in the plan view of FIG. 3, a serpentine magnetron 40 formed in a magnetron plate 42 includes multiple long parallel straight portions 42 arranged on a pitch P smoothly joined by end portions 44, which may be arc shaped or alternatively short straight portions with curved corners connecting to the straight portions 42. Since the magnetrons described herein are generally shaped to form a closed plasma loop, the illustrated pitch P will be called the loop pitch to distinguish it from a track pitch to be described later. The effective area of the serpentine magnetron 40 defined by the outer generally rectangular outline of the magnetic field distribution parallel to the target face is a substantial fraction of target area. The serpentine magnetron 40 may be scanned transversely to the long straight portions 42 across a distance closely related to and of the order of the pitch P in order to completely scan the target area and more uniformly sputter material from that area of the target.

In a related embodiment illustrated schematically in the plan view of FIG. 4, a spiral magnetron 50 includes a continuous series of straight portions 52 and 54 extending along perpendicular axes and smoothly joined together in a rectangular spiral. Neighboring parallel straight portions 52 or 54 are separated by a loop pitch Q. The spiral magnetron 50 may be considered as a number of wraps about a central point of the magnetron. The spiral magnetron 50 may be scanned in one of the rectangular directions over a track pitch Q, which is half of the loop pitch P, for example along the straight portions 54.

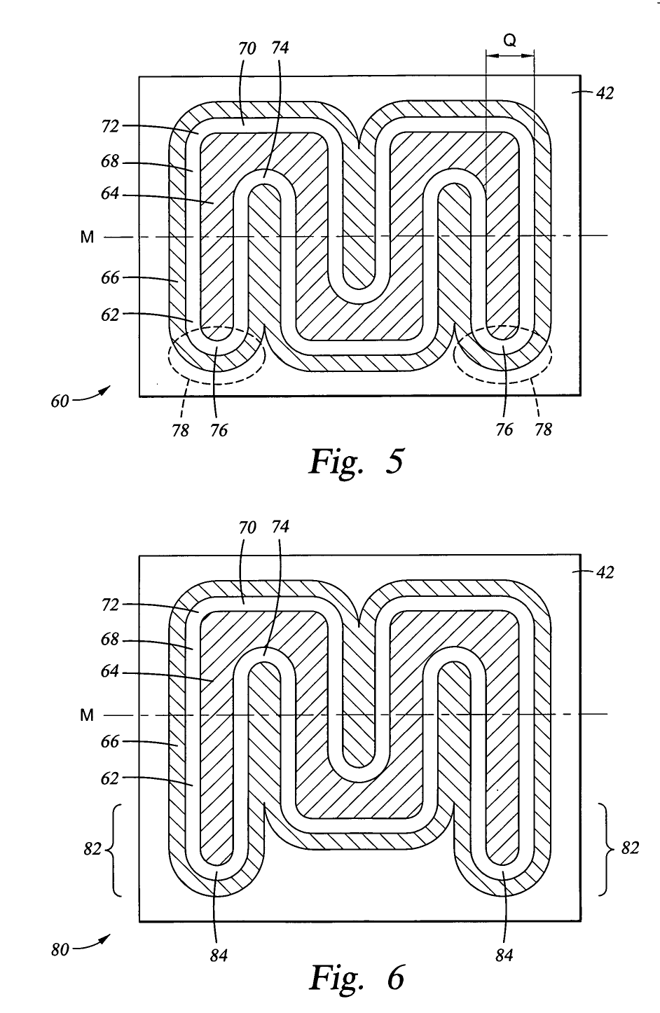

The magnetron shapes illustrated above are somewhat schematic. The number of folds or wraps in the magnetron 40, 50 may be significantly increased. Although it is not necessary, each of the magnetrons may be considered a folded or spirally wrapped version of an extended racetrack magnetron of FIG. 2 with a plasma loop formed between the inner pole and the surrounding outer pole. When the linear magnetron 24 of FIG. 2 is folded, the poles of neighboring folds may merge. As shown in plan view in FIG. 5, a serpentine magnetron 60 is formed of a closed serpentine gap 62 between an inner pole 64 and an outer pole 66 completely surrounding the inner pole 64. The plasma loop, includes two closely spaced anti-parallel propagating plasma tracks separated by a track pitch Q and folded to form a structure that is generally periodic in the illustrated x-direction with a period of the track pitch Q. The single folded track and hence the magnetron have a shape generally following long straight portions 68 extending symmetrically in one direction about a medial line M and shorter straight portions 70 extending in the other directions. Curved portions 72, 74, 76 connect the straight portions 68, 70. The inner curved portions 74 and end curved portions 76 curve sharply around 180°. The figure illustrates that the outermost portions of the outer pole 66 are thinner than the inner portions indicating the relative magnetic flux density. It is understood that the serpentine magnetron 60 may include additional folds of the plasma loop, particularly for larger target sizes.

However, when such a serpentine magnetron 60 was tested, areas 78 of the target underlying the end curved portions 76 of the magnetron 60 demonstrated very low sputtering rates. Rather than increasing the scan length or increasing the entire size of the magnetron, an improved serpentine magnetron 80 illustrated in the plan view of FIG. 6 includes tail portions 82 in which both the inner and outer poles 64, 66 have been extended in the region surrounding end curved portions 84 of the gap 62 so that the end curved portions 84 are outside of a rectangular outline of the useful area of the magnetron 80. As a result, the less eroded regions 78 of FIG. 5 fall outside of the useful target area. The target may need to be enlarged somewhat to accommodate the tail portions 82 but, since little sputtering occurs there, the tail portions 82 may extend closer to the target periphery than the remainder of the magnetron 80 and perhaps may extend over the edge of the target. It is understood there if the plasma loop has an odd number of folds, the two tail portions 82 occur on opposed lateral sides of the magnetron plate 42. A similar tail 78 may extend from the single exterior end of the spiral magnetron 50 of FIG. 4.

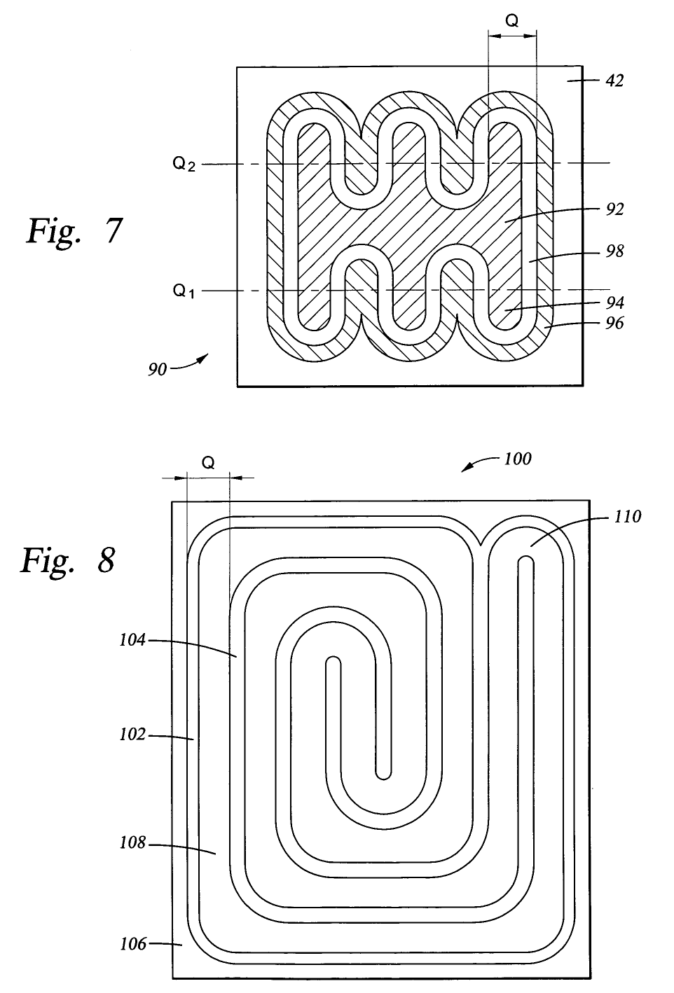

A double-digitated magnetron 90, shown in plan view in FIG. 7 includes an inner pole 92 formed of two opposed rows of generally straight teeth portions 94 and a surrounding outer pole 96 separated from the inner pole by a closed gap 98. The straight portions of the gap 98 are arranged about two general symmetry lines Q₁ and Q₂. The serpentine magnetrons 60, 80 and double-digitated magnetron 90, although visually different, are topologically similar and provide similar magnetic field distributions. Both advantageously have straight portions constituting at least 50% and preferably more than 75% of the total track length. The digitated magnetron is, however, distinguished from the serpentine magnetron 60 and the spiral magnetron to be described later by its inner pole 92 having a complex shape with many projections and not describable in terms of a single path along which the stretched linear magnetron 24 of FIG. 2 is twisted. In contrast, the inner pole of the serpentine and helical magnetrons has a nearly constant width and follows a single convolute or folded path extending from one end to the other. Expressed differently, the inner pole of serpentine and helical magnetrons has only two ends defining ends of the closed plasma loop while the inner pole of the digitated magnetron has three or more ends with many equivalent ends to the plasma loop. As will be described later, these ends cause some difficulty apparently associated with their tight curvature and it may be advantageous to minimize their number. Hope et al. disclose a single-digitated magnetron in U.S. Pat. No. 4,437,966.

A rectangularized spiral magnetron 100 illustrated in plan view in FIG. 8 includes continuous grooves 102, 104 formed in a non-magnetic magnetron plate 106, formed for example out of 6061 aluminum. Unillustrated cylindrical magnets of opposed polarities respectively fill the two grooves 102, 104. The groove 102 completely surrounds the groove 104. The two grooves 102, 104 are arranged on a track pitch Q and are separated from each other by a mesa 108 of substantially constant width. In the context of the previous descriptions the mesa 108 represents the gap between the opposed poles. The one groove 102 represents the outer pole. The other groove 104 represents the inner pole which is surrounded by the outer pole. Similarly to the racetrack magnetron, whether twisted or not, one magnetic pole represented by the groove 104 is completely surrounded by the other magnetic pole represented by the groove 102, thereby intensifying the magnetic field and forming one or more plasma loops to prevent end loss. The width of the outermost portions of the groove 102 is only slightly more than half the widths of the inner portions of that groove 102 and of all the portions of the other groove 104 since the outermost portions accommodate only a single row of magnets while the other groove portions accommodate two rows in staggered arrangements. The grooves 102, 104 of the magnetron 100 may be modified to include a tail portion around a 180° curved end 110 of the mesa 108, similar to the tail portions 82 of FIG. 6. A single magnetic yoke plate may cover the back of the magnetron plate 106 to magnetically couple all the magnets.

The rectangularized spiral magnetron has grooves 102, 104 and hence poles, when populated by magnets, having straight portions extending along perpendicular directions and joined to each other by curved corners. The straight portions advantageously constitute at least 50% and more advantageously 75% of the total length of the pattern.

The grooves 102, 104 generally represent the two poles. However, the structure is more complex. The grooves 102, 104 are machined into the magnetron plate 42 and include arrays of cylindrical holes or serrated edges to capture the individual cylindrical permanent magnets. The cylindrical holes within the thicker portions of the grooves 102, 104 may form two linearly extending parallel rows staggered with respect to each other to increase the magnet packing density. The outside portions of the grooves 102, 104 on the other hand may have only one such linear array. Two optional pole pieces typically formed of magnetically soft stainless steel may have the shape and approximate widths of the grooves 102, 104. Screws fasten the pole pieces to the bottom of the magnetron plate over grooves 102, 104 to both capture the magnets within the downwardly facing grooves 102, 104 and to act as magnetic pole pieces. However, the magnetic yoke may provide sufficient holding force so neither the pole pieces nor screwed fastening means are required.

The number of folds of wraps or folds can be significantly increased. Other convolute shapes for the magnetron are possible. For example, serpentine and spiral magnetrons can be combined in different ways. A spiral magnetron may be joined to a serpentine magnetron, both being formed with a single plasma loop. Two spiral magnetrons may be joined together, for example, with opposite twists. Two spiral magnetrons may bracket a serpentine magnetron. Le et al. describe in provisional application 60/702,327, filed Jul. 25, 2005 and incorporated herein by reference, a double spiral magnetron in which the linear magnetron 24 is first folded to form four parallel plasma tracks and then spirally wrapped around the center. Typically, a single plasma loop is desirable. However, multiple convolute plasma loops enjoy some advantages of the invention.

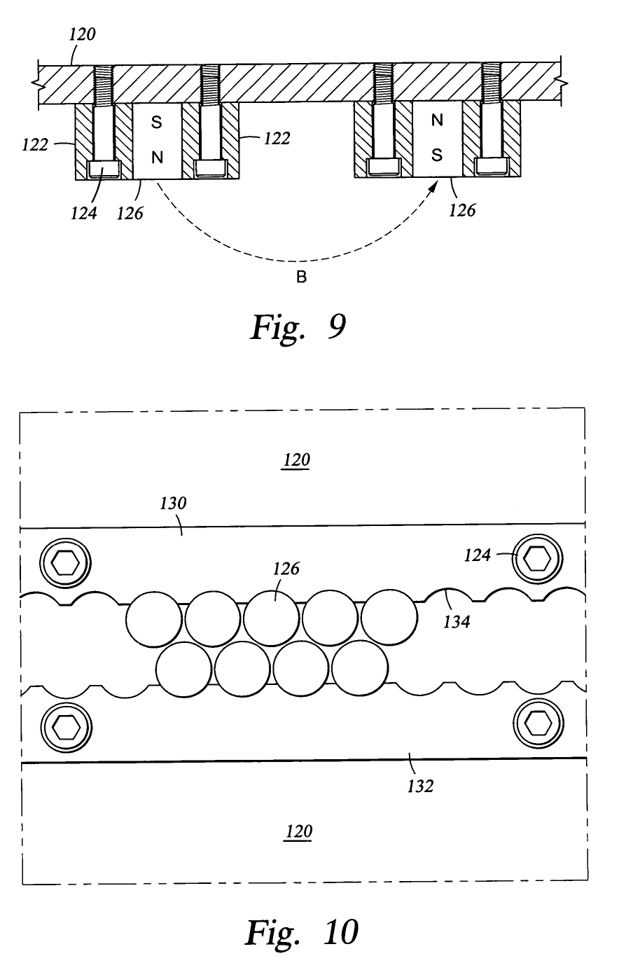

A simpler magnetron construction, illustrated in the cross-sectional view of FIG. 9 and plan view of FIG. 10, has been described by Le et al. in the cited provisional application. A magnetron back plate 120 acts as the main support member for the movable magnetron. It is a thick plate, for example, ½″ (12 mm) thick, formed of a soft magnetic material, such as steel (e.g. cold rolled steel A36) or stainless steel. Non-magnetic retainers 122 are affixed to the bottom of the back plate 120 in its operational orientation by screws 124, preferably formed of non-magnetic material. The retainers 122 may be composed of aluminum (e.g. 6061 Al) or stainless or brass. Cylindrical magnets of selected polarity are loosely fit between two retainers 122 and are held to the back plate 120 by their strong magnetic force. It is possible to include a magnetic pole piece over the exterior side of the magnets 126, but such a pole piece is not required to form an effective pole. If the adjacent magnets 126 have opposed polarities as illustrated, the back plate 120 acts as a magnetic yoke for the backs of the magnets 126 and the opposed magnets 126 produce a magnetic field B between their fronts. The gap between opposed poles should be considered to be the distance between the magnets 126 since the non-magnetic retainers 122 do not interfere with the magnetic field.

The largest portion of the magnetrons 100 includes two adjacent rows of magnets in large part arranged in straight sections. As illustrated in FIG. 10, two straight retainers 130, 132 have facing serrated or scalloped edges with arc-shaped pockets 134 of minimally greater radius than the magnets 126. The screws 124 hold the retainers 130, 132 to the back plate 120 such that the pockets 134 are axially offset from each other by half a magnet diameter and are spaced to accommodate two close-packed rows of magnets 126. The exterior portions of the outer pole typically is filled with only a single row of magnets. The straight retainers 130, 132 in these exterior portions can have similar serrated design but are fixed to the back plate 340 with their pockets 134 aligned to each other with space between to capture a single row of magnets 126. The corner sections joining the straight sections include curved portions which bend the single or double row of magnets by 90°. The corner sections may include similar retainers but having curved portions having different radii. The corner sections may be separately fabricated and screwed to the back plate 120 in alignment with the neighboring straight retainers 130, 132. Le al. describe other aspects of the retainers in the cited provisional application.

The serpentine magnetrons 60, 80 have one principal set of straight sections 68 while the rectangularized spiral magnetron 100 has two sets of parallel straight sections, both of which may be considered principal sets. All the magnetrons 60, 80, 90, 100 benefit from one-dimensional scanning over the pitch P in a direction transverse to one of the principal sets of straight sections. However, such one-dimensional scanning still suffers some deficiencies. First, uniformity of sputtering greatly suffers because there are substantial portions of the magnetron which extend in directions having components parallel to the scan direction. The effect is most pronounced in the serpentine magnetrons 60, 80 in which the short straight sections 70 cause the lateral edges of the target to be eroded more quickly than the central medial portion of the target. The non-uniformity is reduced for the spiral magnetron 100. Nonetheless, these magnetrons still erode the central medial portion of the target less than the more lateral portions. Secondly, unless other precautions are taken, all the magnetrons continue to create a plasma adjacent the lateral edges of the target near the plasma shields. As previously explained for the linear racetrack magnetron, the proximity greatly increases the production of particles during plasma ignition. Thirdly, over erosion continues to result from an end dwell when the magnetron is rapidly and reciprocally scanned.

Sputtering uniformity can be increased by scanning a convoluted magnetron in two orthogonal dimensions over a rectangular target. The scanning mechanism can assume different forms. In a scanning mechanism 140 illustrated in FIG. 11, the target 16 supports on its back, top side a magnetron plate 142 including the magnets through a plurality of insulating pads 144 or bearings held in holes at the bottom of the magnetron plate 142. The pads 144 may be composed of Teflon and have a diameter of 5 cm and protrude from the magnetron plate 142 by 2 mm. Opposed pusher rods 146 driven by external drive sources 148 penetrate the vacuum sealed back wall 22 to push the magnetron plate 142 in opposite directions. The motive sources 148 typically are bi-directional rotary motors driving a drive shaft having a rotary seal to the back wall 22. A lead screw mechanism inside of the back wall 22 converts the rotary motion to linear motion. Alternatively, the lead screw mechanism may be exterior to the sealed back wall 22 and be coupled through the back wall 22 to the pusher rod 146 through a sealed bellows assembly. Two perpendicularly arranged pairs of pusher rods 146 and motive sources 148 provide independent two-dimensional scanning. A single pair of pusher rods 146 and motive sources aligned along the target diagonal provide coupled two-dimensional scanning relative to the sides of the target. Other types of actuators are possible including pneumatic cylinders, stepper motors, and rack-and-pinions, both inside and outside of the low-pressure back chamber.

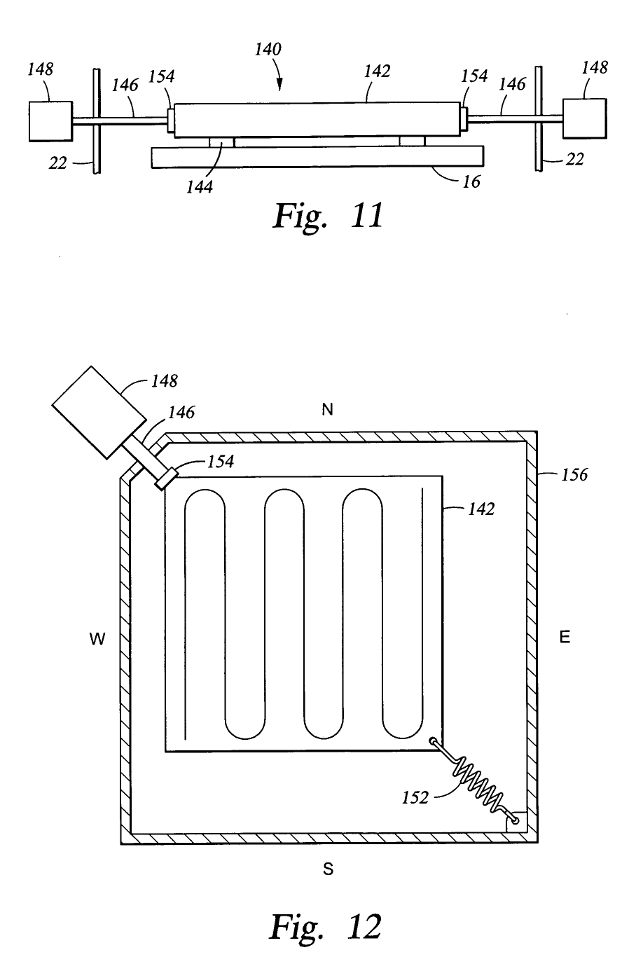

In another embodiment illustrated in the plan view of FIG. 12, a spring 152, preferably a compression spring in the illustrated geometry, may replace one of the opposed pusher rods. Also, a coupling 154 between the pusher rod and the magnetron plate 142 may be fixed so that one rod 146 can both push and pull the magnetron plate 142 in opposition to a tension spring 152 or, in view of the bidirectional actuation in FIG. 11, the coupling 154 may be formed of a rotatable wheel selectively and smoothly pushing the magnetron plate 142. To accomplish a diagonal scanning pattern, a convoluted magnetron formed in a magnetron plate 142, as illustrated in plan view in FIG. 12, is supported within a rectangular frame 156 forming part of the back wall 22. Although a serpentine magnetron is illustrated, other magnetron shapes may be substituted. The actuator 148 coupled to the magnetron plate 142 drives it along a diagonal of the frame 156, that is, in the northwest to southeast direction which is both parallel to and transverse to the direction of the principal set of straight portions of the magnetron. In the illustrated embodiment, the spring 152 acts in opposition to the actuator 148. As a result of the diagonal scanning, the over erosion on the north and south sides of the target is reduced.

It is possible to extend the scan to a back-and-forth scan along the frame diagonal with the plasma so that the magnetron is returned to its original position ready for sputtering onto the next panel. Alternatively, the back scan can be performed with the plasma turned off while a new panel is being placed in the sputter reactor and the sputter chamber is pumped down and equilibrated. In a further alternative, one panel can be sputter deposited during a forward scan and a second panel is deposited during the subsequent back scan.

Other types of scanning mechanisms are possible. The sliding pads 144 can be replaced by wheels or ball or roller bearings, but preferably the wheels or bearings are electrically insulating to leave the magnetron plate 142 grounded while being supported on the biased target 16. For simple motions, a guide plate intermediate the magnetron plate 142 and target 16 guides the scanning. As has been described in the aforecited Halsey patent, the magnetron plate 142 may be supported from above by one or more guide plates through wheels and support rods.

The extent of the scan may be relatively limited. It is generally preferred that the scan length be at least the pitch between neighboring plasma tracks, preferably approximately equal to the pitch or a small multiple thereof. For example, for a magnetron with a pitch of 75 mm between neighboring anti-parallel tracks and designed for a 2 m target, the scan distance should be at least 75 mm. To allow for variable magnet strength and position, it is recommended that the scan distance be at least 10 mm larger than the pitch of the plasma tracks. Scan distances of more than 50% greater than the pitch detract from the advantages of the invention. Experiments have show that scan distances in the range of 85 to 100 mm provide superior erosion. A pitch of 75 mm between magnet grooves and hence between plasma tracks has proven quite effective, indicating a preferred range of 50 to 125 mm for the pitch. An increased number of wraps or folds in the convolute magnetron decreases the required scanning length.

The scanning benefits from two operational characteristics. First, the scanning may be advantageously performed at a relatively low speed of about 1 mm/s so that a complete deposition is performed in a single scan of the frame diagonal or, as will be explained later, in a few such diagonal scans. Very good results have been obtained with a scan speed of 2 mm/s indicating a preferred range of 0.5 to 5 mm/s. For a 100 mm scan, a complete scan can be accomplished in 20 to 200 s. The slow speed simplifies the heavy mechanics. Secondly, it is advantageous to start the slow scan with the plasma extinguished and to strike the plasma after the magnetron has departed from the immediate vicinity of the grounded frame 126, for example, after an initial scan of 2 mm indicating a preferred range of 1 to 5 mm. The delayed striking allows the scan speed to equilibrate. More importantly, however, striking away from the frame 126 significantly reduces the production of particles, which are believed to originate from uncontrolled arcing during the plasma striking.

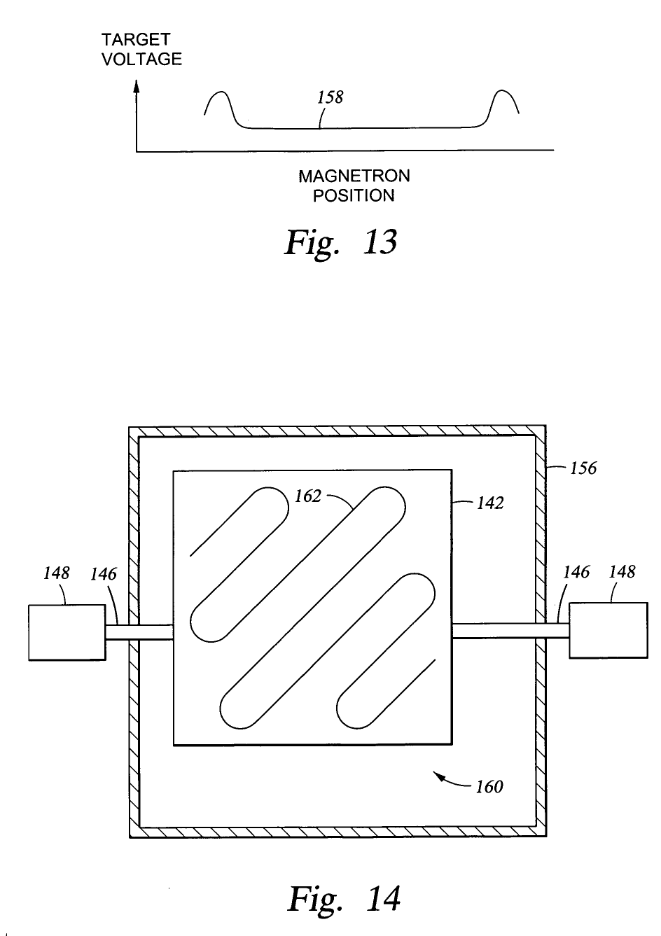

Experiments have been performed in which a linear racetrack magnetron is scanned across the frame with a constant power supply. The target voltage is observed, as indicated by plot 158 in the graph of FIG. 13, to rise from about 500V in the middle to near 600V near the frame 156 or shield, indicating dependence of the plasma impedance upon the magnetron position. This high voltage adjacent the frame is believed to result from electron leakage to the frame 156 and is associated with excessive arcing during striking. If the plasma is instead struck in the flat portion of the curve, arcing is substantially reduced. Advantageously also, the plasma is extinguished before the magnetron reaches the other diagonal corner. If further deposition is to be performed on the same substrate, it is alternatively possible to reduce the target power to achieve a lower-density plasma rather than to completely extinguish the plasma, thereby significantly reducing the generation of particles at the target edge. The same variation of voltage may be applied to a scan perpendicular to the sides of the shield 156 in which the voltage is reduced or the plasma extinguished near the frame 156.

It is also observed that the target voltage with the rectangularized helical magnetron of FIG. 8 is only about 350V, indicating a very efficient magnetron.

A somewhat similar effect to the diagonal scan mechanism of FIG. 12 can be obtained, as illustrated in FIG. 14, with a magnetron 160 formed in the magnetron plate 142 with its one or two principal sets of straight sections 162 formed at an inclined angle with respect to the rectangular coordinates of the frame 156, for example, at 45° or parallel to the frame diagonal. Two opposed actuators 148 aligned along one of the two rectangular coordinates scan the magnetron plate 144 along that coordinate. In this embodiment, the scan is one-dimensional but the magnetron shape is distinctly two-dimensional relative to the frame 156. To avoid edge effects upon striking, extra target space should be provided along the lateral sides.

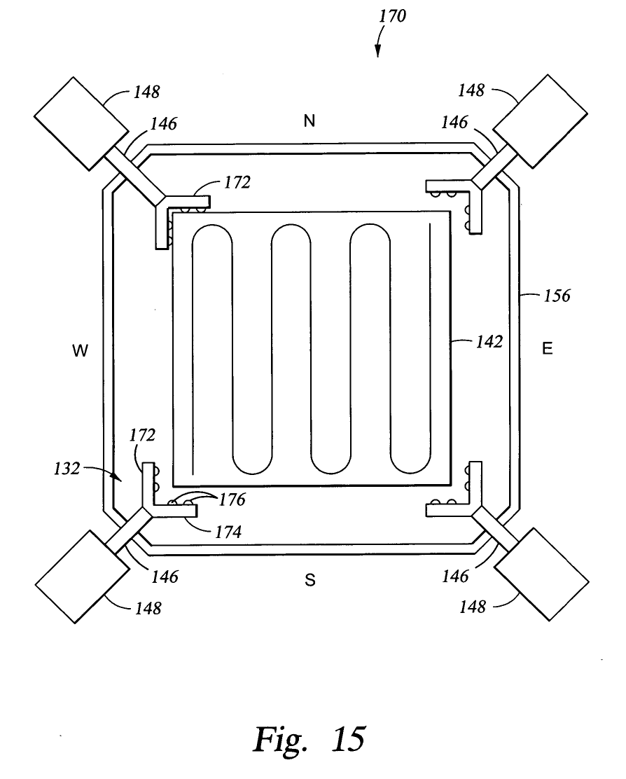

Scanning along two diagonals is achievable with the scan mechanism 170 illustrated in FIG. 15. Four actuators 148 located at the corners of the back wall 22 are aligned in opposed pairs along the two frame diagonals. Each actuator 148 is fixed to a corner pusher 172 having two perpendicular arms 174, each having a plurality of wheels 176 or other sliding means which can smoothly engage and align the respective corners of the magnetron plate 142 to accurately push it along one of the frame diagonals. Although a serpentine magnetron is illustrated, other convolute magnetron shapes may be used with this and other two-dimensional scanning mechanisms. Scanning along either diagonal requires only varying one of the actuators 148. The scanning can be transferred from one diagonal to the other by pushing the magnetron plate 142 along the first diagonal by one of the actuators 148 aligned with that first diagonal to a central point through which the second diagonal passes. Thereafter, one of the actuators 148 aligned with the second diagonal engages the magnetron plate 142 to push it along the second diagonal.

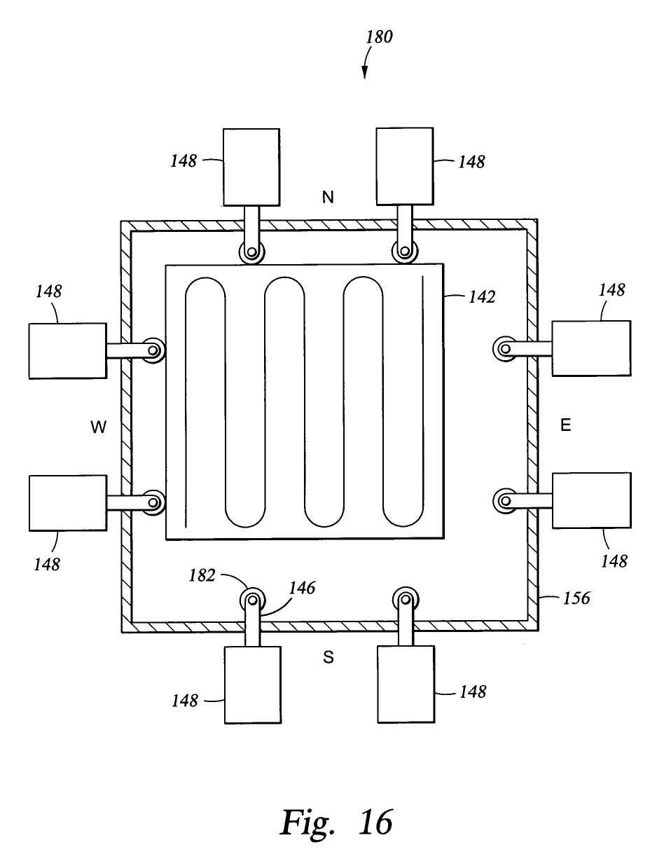

A rectangularly arranged scanning mechanism 180, illustrated in FIG. 16, includes eight actuators 148 arranged in pairs along the four sides of the rectangular frame 126. The paired actuators 148 are controlled alike to execute a same extension of the associated pusher arms 146. The pairing is preferred when the there is no fixed coupling between the actuators 148 and the magnetron plate 142 but only a pushing force is executed. A preferred coupling from the arms 146 of the actuators 148 include respective wheels 182 or other rotatable member on the end of each actuator rod 146. However, soft pusher pads, for example of Teflon, may be substituted for the wheels 182. Only a pair of wheeled actuator pusher rods 146 need to engage the magnetron plate 142 to move it along a Cartesian direction.

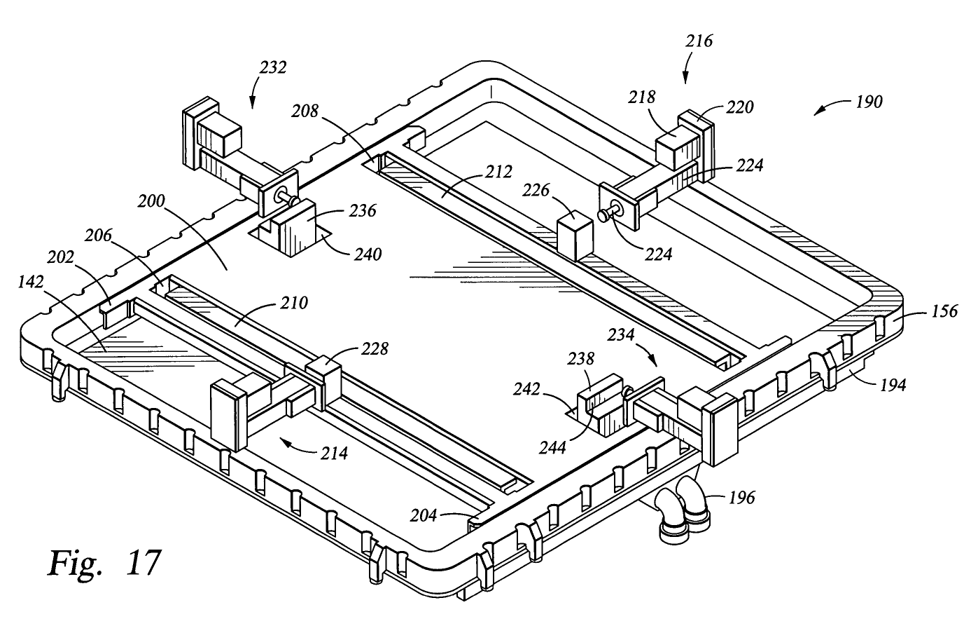

Another scan mechanism 190, illustrated orthographically in FIG. 17, is supported on the frame 156, which in turn is supported on the periphery of the target backing plate. A cooling manifold 194 distributes cooling fluid from supply lines 196 to the target backing plate. Tanase et al. have described an improved cooled backing plate and supply manifold in patent application Ser. No. 11/190,389, filed Jul. 27, 2005, incorporated herein by reference. The Tanase cooling plate has cooling holes laterally drilled in an integral backing plate with cooling liquid manifolds disposed on the planar surface and creating counter-flowing cooling liquid in the plate. The Tanase reference also teaches that the multi-tile target, though generally rectangular, may have corners following the outer plasma track. A slider plate 200 includes two inverted side rails 202, 204 which slide in a first direction along and on top of respective series of wheel bearings mounted on the frame 156. Two slots 200, 208 are formed in the slider plate 200 to extend in the perpendicular second direction. Two inverted rails 210, 212 supporting the magnetron plate 142 extend through the two slots 206, 208 are slidably supported on respective series of wheel bearings mounted on the slider plate 200 to allow motion in the second direction. That is, the magnetron plate 142 and associated magnetron can slide in the perpendicular first and second directions. Further, the heavy magnetron is supported on the frame 156 and the periphery of the target backing plate, itself directly supported on the chamber wall, and not on the relatively thin cantilevered inner portions of the target and target backing plate.

A first set of actuators 214, 216 opposed along the direction of the slider rails 202, 204 are supported on the frame 156 and include respective independently controlled bidirectional motors 218, gear boxes 220, and worm gears 222 driving pusher rods 224, which selectively abut, engage, and apply force to respective bosses 226, 228 extending upwardly from the slider plate 200. A second set of similarly configured actuators 232, 234 opposed along the direction of the magnetron plate rails 210, 212 are supported on the frame 156 to selectively engage respective bosses 236, 238 fixed to the magnetron pate 112 and extending upwardly through holes 240, 242 in the slider plate 210. The through holes 240, 242 are sized significantly larger than the associated bosses 236, 238 to allow the bosses 236, 238 to move the total scan distances in the two orthogonal directions.

The two sets of actuators 214, 216, 232, 234 can be used to move the magnetron plate 142 in orthogonal directions. The bosses 236, 238 fixed to the magnetron plate 142 have relatively wide faces 244 so that the pushers rods 224 of the associated actuators 232, 234 can slidably engage them as the other set of actuators 214, 216 are moving the magnetron plate 142 in the transverse direction.

The illustrated structure is covered by a roof, which is supported on and vacuum sealed to the frame 156 and includes movable vacuum means, for example adjacent to the actuators 214, 216, 232, 234 and in the boss holes 206, 209, 240, 242 to allow the area beneath the roof to be vacuum pumped. The roof includes trusses to withstand atmospheric pressure over the large roof area when the interior is pumped to a relatively low pressure so as to subject the thin target and backing plate to a much reduced pressure differential against the high-vacuum sputter chamber.

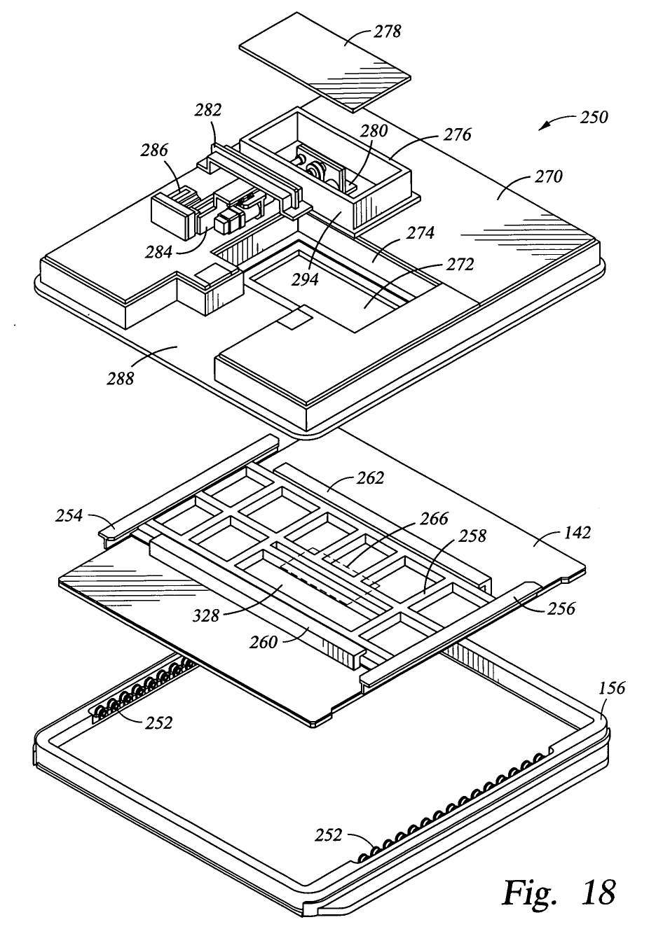

Another scan mechanism 250 is illustrated in the exploded orthographic view of FIG. 18. Two rows of rollers 252 are supported on opposed sides of the frame 156 to rollably support inverted frame rails 254, 256 supporting a gantry 258 between them. The gantry 258 was previously described as a slider plate. The gantry 258 includes two unillustrated rows of rollers for rollably supporting inverted gantry rails 260, 262, from which the magnetron plate 142 depends through fixed connections. The unillustrated rows of rollers are similar to the illustrated rollers 252 but rotate about axles fixed in the gantry 258 beneath the rails 260, 262. By the rolling motion of the gantry 258 and gantry rails 254, 256, 260, 262, the magnetron plate 142 can move in perpendicular directions inside the frame 156. A base plate 266 is fixed to the frame structure forming the gantry 258.

A magnet chamber roof 270, previously referred to as the back wall 22, is supported on and sealed to the frame 156 with the gantry structure disposed between them and provides the vacuum wall over the top of the chamber accommodating the magnetron. The magnet chamber roof 270 includes a rectangular aperture 272 and the bottom of a bracket recess 274. A bracket chamber 276 fits within the bracket recess 274 and is sealed to the chamber roof 270 around the rectangular aperture 262. A top plate 278 is sealed to the top of the bracket chamber 276 to complete the vacuum seal.

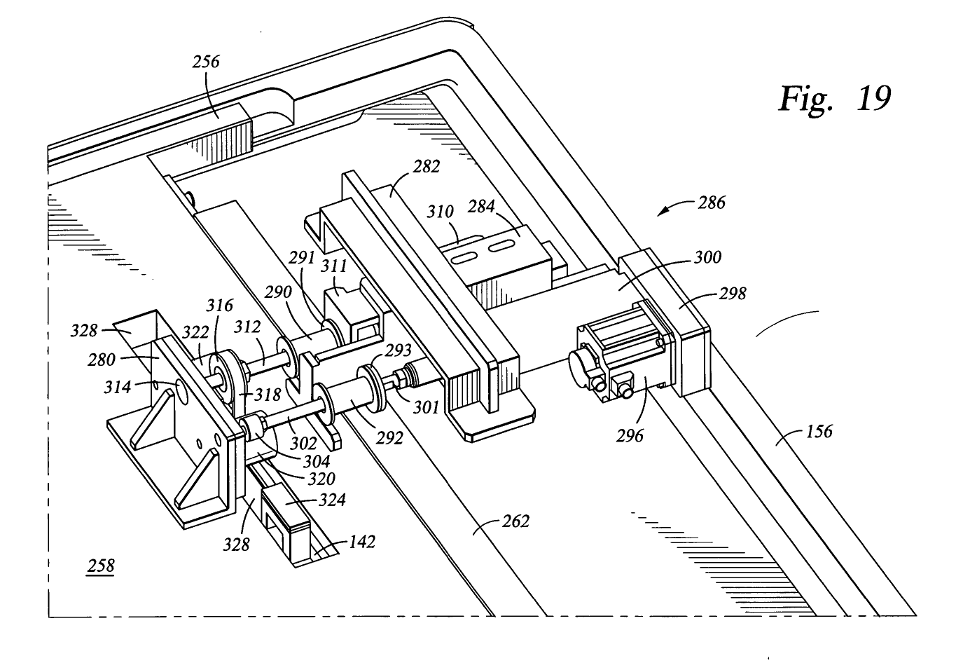

A gantry bracket 280 movably disposed within the bracket chamber 276 is fixed to the base plate 266 of the gantry 258. A support bracket 282, which is fixed to the exterior of the magnet chamber roof 270, and an intermediate angle iron 284 holds an actuator assembly 286 in an actuator recess 288 in the roof 270 outside the vacuum seal. The bracket 282 further acts as part of the truss system in the magnet chamber roof 270. The actuator assembly 286 is coupled to the interior of the bracket chamber 276 through two sealed vacuum ports, as illustrated in the detailed orthographic view of FIG. 19, including bellows 290, 292 penetrating a sidewall 294 of the bracket chamber 276 of FIG. 18. The bellows 290, 292 are respective axially corrugated integral tubular members of sufficient elasticity to allow expansion along the actuator axes of a distance as great as the scan distance along the frame side rails 254, 256. The bellows 290, 292 have one end sealed around apertures in the sidewall 294 and another end having a vacuum sealed cap 291, 293.

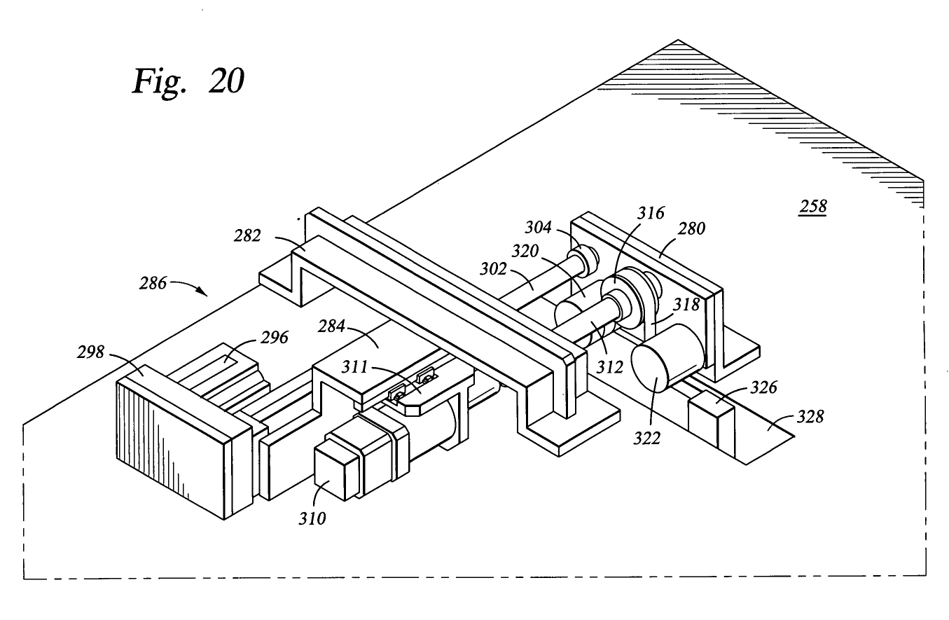

The actuator assembly 286, also illustrated from the opposite lateral side in the orthographic view of FIG. 20, includes two actuators. The latter figure includes the actuator assembly 286 and the gantry 258 but not the intermediate magnet chamber roof 270. FIGS. 19, 20 both illustrate a plate structure for the gantry 258 rather than the frame structure of FIG. 18.

A linear actuator includes a first stepper motor 296, a gear box 298, and a worm gear 300. An actuator rod 301 linearly driven by the worm gear 300 is connected to the end cap 293 of the bellows 292, which is solid, and a push rod 302 connected to the other side of the end cap 293 is fixed to the gantry bracket 280 through a screwed fixture 304. However, other linearly vacuum ports are possible. For example, the lead screw mechanism could be incorporated into a lead nut rotating in the gantry bracket 280 and a lead screw formed in the end of a rotary output shaft of the first stepper motor 296 penetrating into the vacuum chamber through a rotary seal.

A rotary actuator includes a second stepper motor 310 supported on the angle iron 284 through a linear slide 311 and having a rotary output shaft 312, which penetrates the sealed bracket chamber sidewall 294 through the bellows 290, which includes a rotary seal in its end cap 291 for the rotary shaft 312. The linear slide 311 allows the second stepper motor 310 and its output shaft 312 to move along the axis of the rotary shaft 312 relative to the roof 270 and frame 156. Other means are possible for the vacuum port transmitting linear and rotational movement. The other end of the rotary shaft 312 is supported by a bearing 314 held in the gantry bracket 280. The rotary shaft 312 holds a toothed pulley or capstan 316 around which is wrapped a ribbed belt 318. Two pulleys or rollers 320, 322 lead the ribbed belt 318 downwardly and then outwardly towards its two ends, which are fixed to two pedestals 324, 326, which are fixed to the magnetron plate 142 and extend upwardly through a hole 328 in the gantry 258. The belt structure cam be replaced by other structures. For example, a pinion gear on the rotary shaft 312 engages a toothed rack on the magnetron plate 142.

In combination, the linear actuator causes the gantry 258 to move along the direction of the frame side rails 254, 256 and the rotary actuator causes the magnetron plate 142 to move along the direction of the gantry side rails 260, 262 fixed to the gantry 258.

The scan mechanism 190 of FIGS. 17-19 provides a fixed connection between the two actuators and the magnetron plate 142 to provide for respective independent perpendicular bidirectional movements in contrast to the unidirectional or sliding connections or contact of the other embodiments, which require four or more actuators for full perpendicular movements.

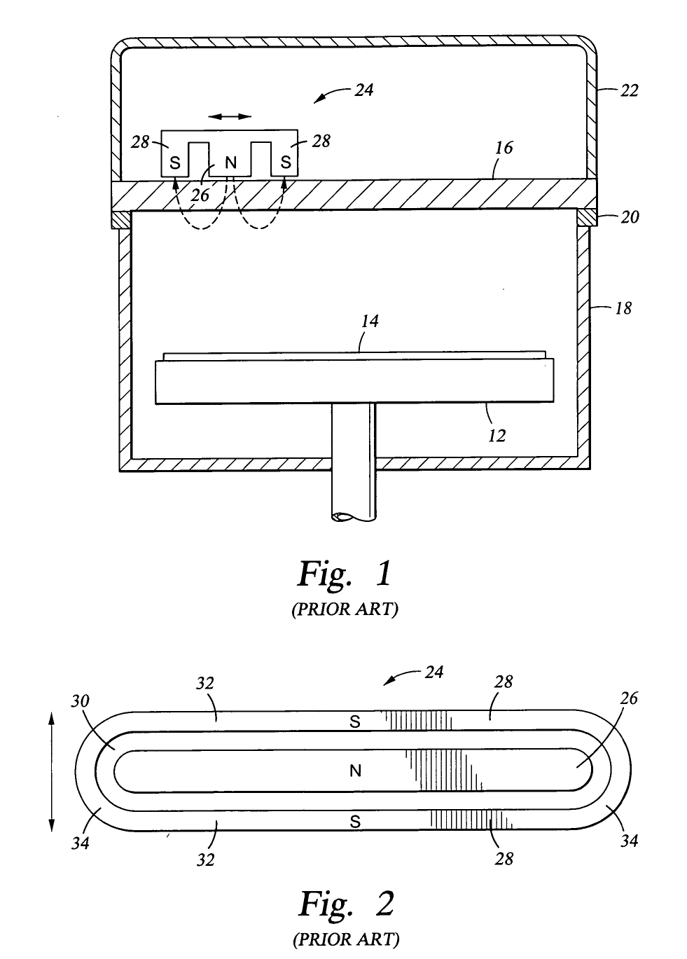

The reactor of FIG. 1 is typically controlled by an unillustrated computerized control system operating in accordance with a recipe set for processing a sequence of panels 14. The control system controls a DC power supply powering the target 16, a vacuum pumping system pumping the interior of the sputtering chamber 18 and the back chamber 22 to desired low pressures, a slit valve connecting the chamber interior to a transfer chamber, and a robot disposed principally within the transfer chamber to transfer substrates 14 in and out of the sputtering chamber 18. The control system is additionally connected to the actuators of the various embodiments to scan the large magnetron in a desired 2-dimensional pattern in back of the target 16.

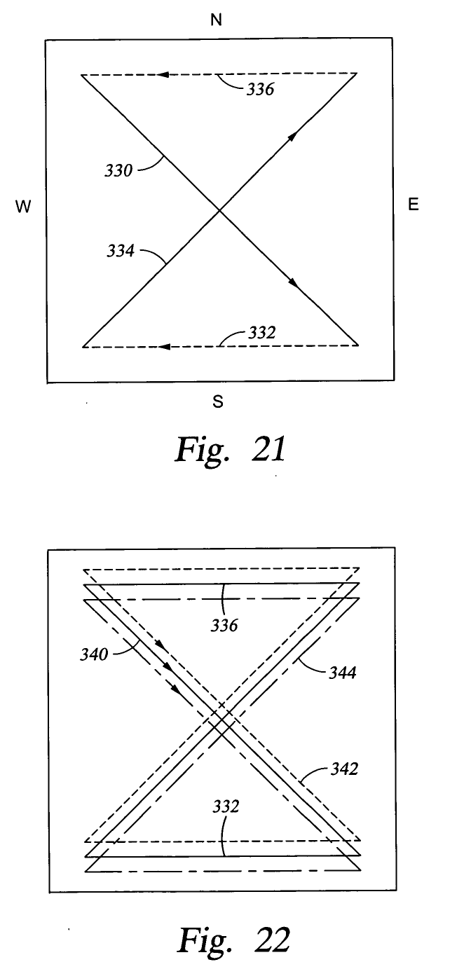

Multiple actuators may be controlled in combination to effect a desired scanning pattern. One mode of simultaneous operation smoothly follows the diagonal scan of FIG. 12, for example, northwest to southeast although a southwest to northeast scan is also possible. A second mode of operation improves the erosion uniformity by scanning, as illustrated in the map of FIG. 21, a complete double-Z pattern by performing the first deposition scan 330 along one diagonal direction and extinguishing the plasma (or reducing the target power) near the end of the diagonal scan 330. Thereafter, the magnetron is scanned near the target edge along the a rectangular path 332 parallel to one Cartesian coordinate with the plasma extinguished or lessened. Then, a second deposition scan 334 with active plasma is performed along the other diagonal but the plasma is extinguished near the end of the second diagonal 334. Finally, the magnetron is scanned back along a rectangular path 336 near the other target edge and anti-parallel to the one Cartesian (rectangular) coordinate with the plasma extinguished. This pattern will be referred to as a double-Z. It is noted that the indicated paths extend only over the scan dimensions, e.g. 75 or 100 mm, and not over the entire target having sides about 10 times or more larger. That is, the magnetron has an effective magnetic field extending within an area with sides that are 80% or 90% or even greater of the corresponding dimensions of the target within the frame. With reference to a serpentine magnetrons 60, 80 of FIGS. 5 and 6, the double-Z scan can be performed so that the edge scans 332, 336 are performed either parallel to the principal set of straight sections 68 or perpendicular thereto.

The double-Z scan can be performed for a single substrate. Alternatively, a fresh substrate can be substituted during each of the rectangular scans 332, 336 while no plasma is excited and the chamber pressure and gaseous ambient are relatively unimportant. If the size of the double-Z pattern is small enough so that edge effects are avoided in the edge paths 332, 336 in the presence of a plasma, an advantageous scan pattern starts at the center at which the plasma is ignited. The plasma remains ignited while the magnetron is scanned through the complete double-Z pattern, finally ending back at the center. The plasma ignition thus occurs at the maximum distance from any portion of the grounded frame 156.

The double-Z scan and other types of scan need not be precisely replicated from one step to the next. Target erosion uniformity, which determines target lifetime, can be improved by offsetting sequential double-Z scans in one or two directions. For example, as illustrated in the map of FIG. 22 after a first, baseline double-Z scan 340, the pattern is displaced along one Cartesian coordinate by a small distance, for example, 10 mm, and preferably perpendicular to the side portions 332, 336 of the double-Z scan for performance of a second double-Z scan 342. A range for the offset is 5 to 15 mm, preferably 8 to 12 mm. Further uniformity is achieved by an equal displacement in the opposite direction from the baseline scan 340 for performance of a third double-Z scan 344. Thereafter, the scan pattern may return to the baseline scan 340. Further offset values may be used. The various parts of the complete scan may be performed for deposition onto one substrate or onto multiple, sequentially inserted substrates. One complete double-Z scan is advantageously performed in sputter depositing on one substrate and a subsequent displaced double-Z scan is performed on a subsequent substrate.

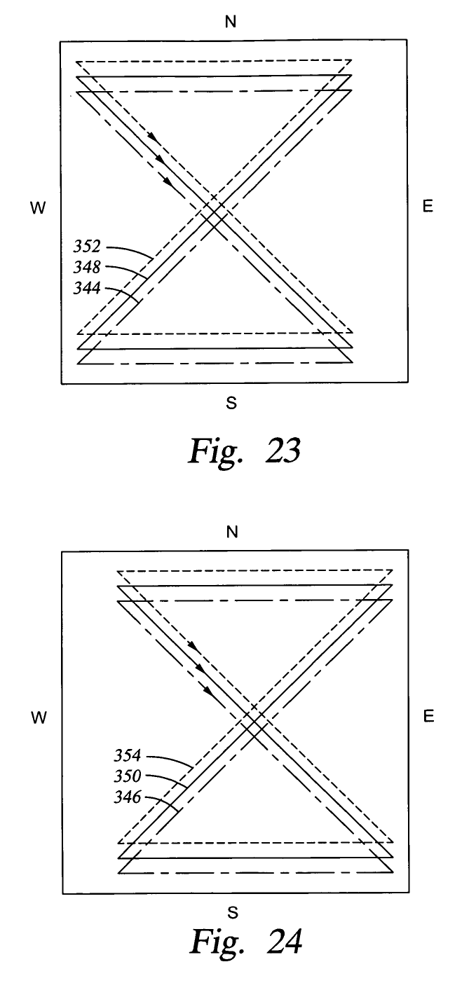

The displacement of double-Z scans may be performed in two directions as illustrated in the map sequentially illustrated FIGS. 23 and 24. Although the exact sequence is not crucial, a first double-Z scan 344 of FIG. 23 includes the nearest usable point to the southwest corner and does not extend all the way to the usable area on the east side. A second double-Z scan 346 of FIG. 24 is displaced toward the east side to include the nearest usable point to the southeast corner. In one method of sputtering, each double-Z scan 344, 346 is used for each panel to be sputter coated. Returning to FIG. 23, a third double-Z scan 348 is displaced toward the north side from the first double-Z scan 344. For example, the second scan 346 may be displaced a distance Z in the x-direction from the first scan 344 and the third scan 348 may be displaced a same or different distance Z in the y-direction from the first scan 344. The process is then repeated for fourth, fifth, and sixth double-Z scans 350, 352, 354. The process may then continue for additional double-Z scans, for example, ten total scans, until the nearest usable points to both the northwest and northeast corners are scanned. It is also possible to have more than two displacements from west to east.

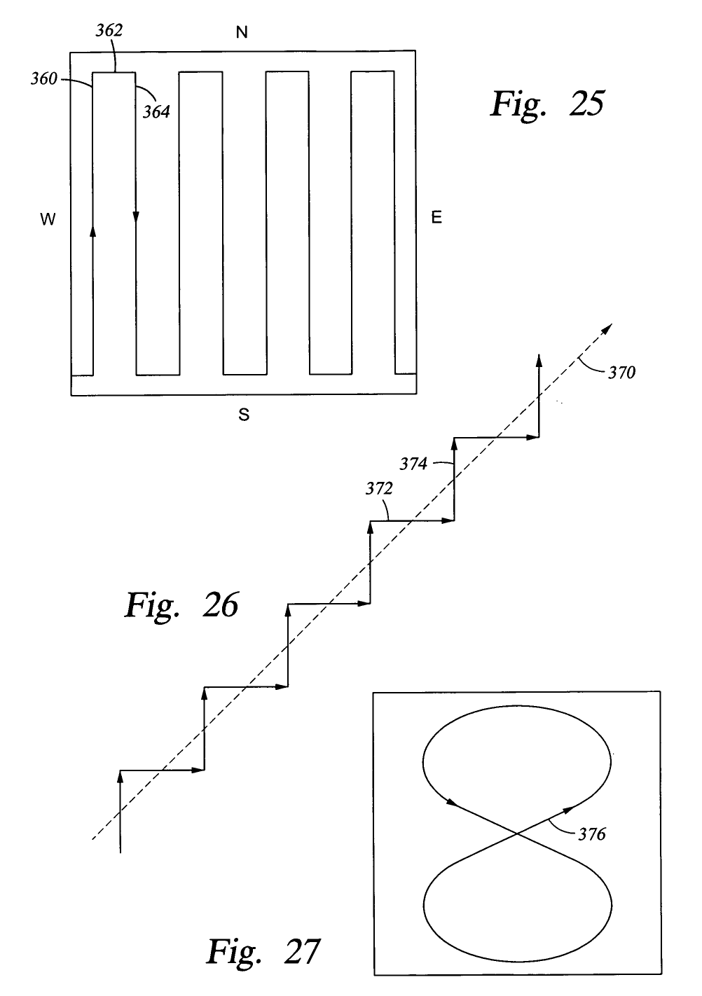

A single double-Z scan may take about one minute, which is sufficient for layers sputtered to a thickness of, for example, 1 μm. However, there are some layers which need to be deposited to a much reduced thickness. One advantageous scan pattern, especially for short deposition times is the serpentine pattern of FIG. 25. A first linear scan 360 extends along one side of total scan area between two opposed sides during which the plasma is turned on and sputter deposition occurs. The first linear scan 360 may be short enough to sputter coat the required thickness on a first panel. The scan is then displaced in the perpendicular direction in a first perpendicular scan 362 along a second side of the total scan area perpendicular to the first side. The perpendicular scan 362 may be performed with the plasma extinguished and while a second panel replaced the first panel in the sputter chamber. Then a second linear scan 364 anti-parallel to the first linear scan 360 is performed with the plasma turned on to sputter coat the second panel with the same thin layer of sputtered material. The plasma is turned off while the scan is again displaced in the perpendicular direction and a third panel replaces the second panel in the sputter chamber. The process continues until the useful scanning area is exhausted. The process then repeats, either from the beginning point or retracing the previous scan in the reverse direction or some other similar scan path, including interchanging the directions of the linear and perpendicular scans.

It is possible to simultaneously activate two perpendicularly arranged actuators to cause the magnetron to move along a diagonal path 370 illustrated in FIG. 26. However, in some situations it is instead preferred to follow a zig-zag path consisting of small movements 372 along one Cartesian coordinate alternating with small movements 374 along the other, perpendicularly arranged Cartesian coordinate. For example, each movement 372, 374 may be about 1 mm. A range of lengths of the movements 372, 374 is 0.4 to 3 mm, preferably 0.8 to 1.2 mm. If the diagonal path 370 is not arranged at 45° with respect to the Cartesian coordinates, the movements 372, 374 may have different lengths between them to approximate the diagonal scan 370. If it is difficult to provide the precise ratio of perpendicular movements, for example, with a stepper motor, then different movements in the same direction may have different lengths that on average produce the overall path 370 in the desired direction. This alternating movement achieves a larger effective scan area to increase the sputtering uniformity. The alternating movement is further advantageous with the perpendicularly arranged pushing actuators of FIG. 17, which do not include a rolling mechanism against the magnetron plate or fixed connections to it. In this situation, simultaneous movement in perpendicular directions cause at least one of the rod contacts to slide against the magnetron plate or the boss or gantry bracket. In contrast, with the alternating movement, the actuator not being used can be backed away from the magnetron plate so as to not contact the magnetron plate as it moves laterally past.

Experiments have demonstrated that rectangular targets can be substantially uniformly over a central area extending to within 150 mm of the frame. Uniformity in one direction can be extended by increasing the length of the straight portions of the serpentine magnetron while uniformity in the other direction is increased by the magnetron scanning.

The full set of actuators allow more complex, nearly arbitrary scan patterns, possibly including curved portions. For example, a figure-8 scan 376 shown in FIG. 27 can be achieved by continuously varying the control of the four sets of actuators. The figure-8 scan 376 is an example illustrating the nearly arbitrary scanning pattern achievable with the invention.

Many of the advantages of the invention can be achieved if two-dimensional scanning or delayed plasma ignition is applied to a convention magnetron composed of a plurality of parallel but independent linear magnetrons 24 of FIG. 2 formed with plural parallel inner poles 26 all surrounded by a single outer pole 32 with multiple parallel openings for the inner poles 26 and the respective plasma loops. However, the convolute single plasma loops of the serpentine and helical magnetrons of the invention are believed to provide more efficient and controllable sputtering.

The different aspects of the invention provides more uniform target erosion and sputter deposition with very large rectangular sputter targets. The convolute magnetrons are achievable with little increased cost. The two-dimensional scanning requires additional complexity in the scan mechanism, but the slow scanning, particularly along a reduced scan length with a large magnetron, reduces the bulk and cost of the scan mechanism.

1. In a plasma sputter reactor which having a chamber and is fittable with a rectangular target for sputtering depositing material of the target onto a rectangular substrate and a magnetron formed in a magnetron plate disposable on a back of the target opposite the substrate, a scan mechanism comprising:
a gantry supported on two opposed sidewalls of the chamber, slidable in a first direction, and configured to support the magnetron plate depending therefrom and allow it to slide in a second direction orthogonal to the first direction;
a first actuator coupled to the gantry to move it in the first direction;
a second actuator couplable to the magnetron plate to move it in the second direction.

2. The scan mechanism of claim 1, further comprising:
a first pair of sets of rollers arranged in the first direction and supported in the two opposed sidewall and rollably supporting the gantry; and
a second pair of sets of roller arranged in the second direction and supported in the gantry and rollably supporting the magnetron plate.

3. The scan mechanism of claim 1, wherein said first actuator also moves the second actuator in the first direction.

4. The scan mechanism of claim 1, wherein the target, magnetron, and gantry are disposed inside the chamber which is vacuum pumped and wherein the actuators are disposed outside of the chamber.

5. The scan mechanism of claim 4, wherein an output shaft of the first actuator is coupled through a wall of the chamber by a bellows assembly having a sealed end plate and an output shaft of the second actuator is coupled into the chamber through a bellows assembly including a rotary seal at an end thereof.

6. The scan mechanism of claim 1, wherein an output of the first actuator moves the gantry in opposed orientations of the first direction and the second actuator moves the magnetron plate in opposed orientations of the second direction.

7. The scan mechanism of claim 1, wherein an output shaft of the first actuator is fixed to the gantry.

8. The scan mechanism of claim 1, further comprising:
a rotary output shaft of the second actuator;
a pulley fixed to the rotary output shaft;
a belt wrapped at least partially around the pulley and having ends fixed to the magnetron plate.

9. In a plasma sputter reactor which having a chamber and is fittable with a rectangular target for sputtering depositing material of the target onto a rectangular substrate and a magnetron formed in a magnetron plate disposable on a back of the target opposite the substrate, a scan mechanism comprising:
a first actuator fixedly connected to the magnetron plate to move it in anti-parallel first directions; and
a second actuator fixed connected to the magnetron plate to move it in anti-parallel second directions perpendicular to the first directions.

10. The scan mechanism of claim 9, wherein the first and second actuators are independently operated.

11. The scan mechanism of claim 9, wherein the first actuator is a linear actuator and the second actuator is a rotary actuator.

12. The scan mechanism of claim 11, wherein the second actuator is mounted on a slider movable by the first actuator.

13. A method of sputtering onto a rectangular substrate, comprising the step of scanning a magnetron in back of a sputtering target along a first two-dimensional multi-part path having at least straight portion.

14. The method of claim 13, wherein the first path is a double-Z path having two parallel portions and two crossing portions connecting respective pairs of ends between the two parallel portions.

15. The method of claim 13, wherein the second path is a serpentine path.

16. The method of claim 13, further comprising scanning the magnetron in back of the sputtering target along a second two-dimensional multi-part path offset from the first path along a first direction.

17. The method of claim 16, further comprising scanning the magnetron in back of the sputtering target along a third two-dimensional multi-part path offset from the first path along a second direction perpendicular to the first direction.

18. A method of sputtering onto a rectangular substrate, comprising the step of scanning a magnetron in back of a substantially rectangular sputtering target along a path having straight portions non-parallel to each other.

19. The method of claim 18, wherein the magnetron is substantially rectangular and forms a closed plasma loop having a convolute shape.

20. The method of claim 18, wherein the magnetron is scanned in a double-Z patterns along two opposed sides of a rectangle aligned with the target and along diagonals connecting ends of the two opposed sides.

21. The method of claim 18, wherein the magnetron is scanned in a plurality of the double-Z patterns offset from each other.

22. The method of claim 21, wherein the plurality of the double-Z patterns are offset from each other in a combination of orthogonal offsets.

23. The method of claim 18, wherein the magnetron is scanned in a serpentine pattern having first straight portions each extending substantially across a first scan distance in a first direction and second portions each extending only across a respective second scan distance less than the first scan distance and in a second direction orthogonal to the second direction.
